(19) United States
(12) Patent Application Publication
(10) Pub. No.: US 2025/0089213 A1
(43) Pub. Date: Mar. 13, 2025

(54) NOVEL HEAT PIPE CONFIGURATIONS

(71) Applicant: HONEYWELL INTERNATIONAL INC., Charlotte, NC (US)

(72) Inventors: Tao Liu, Shanghai (CN); Yong Zhou, Shanghai (CN); Enxin Lin, Shanghai (CN)

(73) Assignee: HONEYWELL INTERNATIONAL INC., Charlotte, NC (US)

(21) Appl. No.: 18/916,246

(22) Filed: Oct. 15, 2024

Related U.S. Application Data
(63) Continuation of application No. 17/503,243, filed on Oct. 15, 2021, now abandoned.

(30) Foreign Application Priority Data
Oct. 16, 2020 (WO) PCT/CN2020/121546

(51) Int. Cl. H05K 7/20; F28F 23/02; H04M 1/02; H05K 1/02

(52) U.S. Cl. CPC H05K 7/20336; F28F 23/02; H04M 1/0277; H05K 1/0203; H05K 7/20309; H05K 7/20318; H05K 7/20327; F28F 2210/02

(57) ABSTRACT

Disclosed are heat pipes of the type having a condenser section in which gaseous refrigerant is condensed to produce liquid refrigerant comprising:
(a) at least one closed pipe comprising:
   (i) a condenser section,
   (ii) a first evaporator section in fluid communication with said condenser section; and
   (iii) at least a second evaporator section in fluid communication with said condenser section;
(b) refrigerant contained in said heat pipe;
(c) at least a first liquid flow path leading a first portion of liquid refrigerant condensed in said condenser section to said first evaporator section; and
(d) at least a second liquid flow path leading a second portion of liquid refrigerant condensed in said condenser section to said second evaporator section, wherein said second evaporator section comprises a reservoir holding liquid refrigerant at a location different than said first evaporator section.

### CROSS REFERENCE

The present application is a continuation of U.S. patent application Ser. No. 17/503,243, filed on Oct. 15, 2021, which claims the priority benefit of PCT/CN2020/121546, filed on Oct. 16, 2020, each of which is incorporated herein by reference in their entirety.

### FIELD

The present invention relates to novel heat pipe configurations, and in particular to methods and systems which utilize same.

### BACKGROUND

As used herein, the term “heat pipe” means a heat transfer device which includes a liquid heat transfer fluid in an evaporating section and vaporous working fluid in a condensing section and which uses the motive force of vaporization to move the vaporous fluid from the evaporating section to the condensing section and little or no energy input to move the liquid working fluid back to the evaporating section.

One of the most common types of heat pipes is depicted in Figure A, which is commonly known as a gravity-return heat pipe or thermosiphon heat pipe. This type of heat pipe relies, at least in part, on the force of gravity to return the liquid working fluid from the condensing section to the evaporating section. As illustrated in Figure A, in a typical configuration the heat pipe is a sealed container arranged vertically with an evaporating section located in a lower portion of the pipe and a condensing section located in an upper portion of the pipe. The evaporating section contains a working fluid in liquid form that absorbs heat from the item, body or fluid to be cooled and is thereby boiled to form a vapor of the working fluid. Boiling of the working fluid in the evaporation section causes a pressure differential and drives the vapor into the condensing section. Vaporous working fluid in the condensing section releases heat to the chosen heat sink (for example, ambient air) and is thereby condensed to form liquid working fluid at or proximate to the inside surface of the heat pipe. This liquid then returns under the force of gravity to the evaporating section and joins the liquid working fluid contained there.

As mentioned above, boiling increases the mass of vapor in the evaporating section, and since the mass of vapor is reduced in the condensing section, a pressure differential is created which drives the vapor from the boiling section to the condensing section, thus creating a continuous heat transfer cycle that requires no energy input (other than the heat absorbed in the cooling operation) to transport the working fluid from the evaporator section to the condenser section.

In some applications it is desired to arrange the heat pipe horizontally or at an incline. In the case where the heat pipe is arranged fully horizontally, it is common that the heat pipe is known as a capillary-return heat pipe, or wicking heat pipe, an example of which is shown in Figure B.

In an arrangement of the type shown in Figure B, heat is absorbed into the liquid working fluid in the evaporating section (shown on the left in Figure B) causing the liquid to boil, which as described above provides a pressure differential to move the vapor to the condensing section. However, rather than relying solely on the force of gravity to return condensed liquid working fluid, a wicking structure is provided adjacent to the container wall that causes, through capillary action, a flow of the condensed working fluid to return from the condensing section to the evaporating section. Although the capillary return heat pipe in Figure B is illustrated in a vertical position, it will be appreciated that capillary return heat pipe can be oriented in virtually any orientation depending on the needs and specific geometry and capillary force needed for a given application. Accordingly, the term “capillary-return” heat pipe as used herein includes heat pipes that have a capillary return force, independent of the orientation of the heat pipe.

Other heat pipes configurations that also use little or no additional energy to return the working fluid condensate to the evaporating section include electrohydrodynamic heat pipe (which use electrokinetic force), electro-osmotic heat pipe, magnetohydrodynamic heat pipe (which use magnetic forces), osmotic heat pipe and oscillating heat pipe.

As a result of the very high heat transfer coefficients for boiling and condensation, heat pipes are highly effective thermal conductors. Heat pipes are therefore used in many applications, particularly electronic device cooling. One important application for heat pipe cooling is to remove heat from a plurality of components, including for example microchips, mounted on a printed circuit board. For the purposes of illustration, a vertically mounted printed circuit board (PCB) C1 with three components to be cooled, C2, C3 and C4, mounted on the printed circuit board. The components C2, C3 and C4 generate heat during operation and need to have heat removed therefrom by a gravity return heat pipe C5, which is mounted in thermal communication with each of the components C2, C3 and C4. Because of the limitations associated with prior heat pipes, it has heretofore been common to design the configuration of the circuit board such that the heat generating components are located on the circuit board to ensure that they can be adjacent to the lower part of the heat pipe since this is where the liquid phase of the working fluid will mostly be present. Furthermore, according to prior practice it was not possible to substantially increase the size of the evaporator section without sacrificing the size and performance of the condenser section, which is also critical to overall heat pipe performance.

Applicants have come to appreciate also that improvements in PCB cooling performance, and the process even of designing PCB layout, can be dramatically improved by utilizing novel heat pipe configurations as disclosed herein. Furthermore, the novel heat pipe configurations of the present invention can be advantageously used for cooling many types of devices and system other than PCBs and electronic systems.

### SUMMARY

The present invention provides a heat pipe of the type which has a condenser section in which gaseous refrigerant is condensed to produce liquid refrigerant comprising:
(a) at least one closed pipe comprising:
   (i) a condenser section,
   (ii) a first evaporator section in fluid communication with said condenser section; and
   (iii) at least a second evaporator section in fluid communication with said condenser section;
(b) refrigerant contained in said heat pipe;
(c) at least a first liquid flow path leading a first portion of liquid refrigerant condensed in said condenser section to said first evaporator section; and
(d) at least a second liquid flow path leading a second portion of liquid refrigerant condensed in said condenser section to said second evaporator section, wherein said second evaporator section comprises a reservoir holding liquid refrigerant at a location different than said first evaporator section.
   For the purpose of convenience, heat pipes according to this paragraph are referred to herein as Heat Pipe 1.

The present invention provides a heat pipe of the type which has a condenser section in which gaseous refrigerant is condensed to produce liquid refrigerant comprising:
(a) at least one closed pipe comprising:
   (i) a condenser section,
   (ii) a first evaporator section in fluid communication with said condenser section; and
   (iii) at least a second evaporator section in fluid communication with said condenser section;
(b) refrigerant contained in said heat pipe, wherein the heat pipe is configured to use gravity at least in part to return refrigerant liquid to from said condenser section to said first and said second evaporator section;
(c) at least a first liquid flow path leading a first portion of liquid refrigerant condensed in said condenser section to said first evaporator section; and
(d) at least a second liquid flow path leading a second portion of liquid refrigerant condensed in said condenser section to said second evaporator section, wherein: (i) said second liquid flow path comprises one or more obstructions oriented at an angle with respect to the vertical direction and to divert at least a portion of said liquid refrigerant from said condenser section toward said second evaporator; and wherein said second evaporator section comprises a reservoir holding liquid refrigerant at a location different than said first evaporator section.
   For the purpose of convenience, heat pipes according to this paragraph are referred to herein as Heat Pipe 2.

The present invention provides a heat pipe of the type which has a condenser section in which gaseous refrigerant is condensed to produce liquid refrigerant comprising:
(a) at least one closed pipe comprising:
   (i) a condenser section which uses gravity at least in part to return refrigerant liquid to from said condenser section to said evaporator section,
   (ii) a first evaporator section in fluid communication with said condenser section;
   (iii) a second evaporator section in fluid communication with said condenser section and located intermediate of said first evaporator section and said condenser section; and
   (iv) at least a third evaporator section in fluid communication with said condenser section and located intermediate of said first evaporator section and said condenser section;
(b) refrigerant contained in said heat pipe, wherein the heat pipe is configured to use gravity at least in part to return refrigerant liquid to from said condenser section to each of said first, second and third evaporator sections;
(c) at least a first liquid flow path leading a first portion of liquid refrigerant condensed in said condenser section to said first evaporator section;
(d) at least a second liquid flow path leading a second portion of liquid refrigerant condensed in said condenser section to said second evaporator section, wherein: (i) said second liquid flow path comprises one or more obstructions oriented at an angle with respect to the vertical direction and divert at least a portion of said liquid refrigerant from said condenser section toward said second evaporator; and wherein said second evaporator section comprises a reservoir holding liquid refrigerant at a location different than said first evaporator section; and
(e) at least a third liquid flow path leading a third portion of liquid refrigerant condensed in said condenser section to said third evaporator section, wherein: (i) said third liquid flow path comprises one or more obstructions oriented at an angle with respect to the vertical direction and which divert at least a portion of said liquid refrigerant from said condenser section toward said third evaporator; and wherein said third evaporator section comprises a reservoir holding liquid refrigerant at a location different than said first evaporator section and different than said second evaporator section. For the purpose of convenience, heat pipes according to this paragraph are referred to herein as Heat Pipe 3.

The present invention provides a heat pipe of the type which has a condenser section in which gaseous refrigerant is condensed to produce liquid refrigerant comprising:
(a) at least one closed pipe comprising:
   (i) a condenser section,
   (ii) a first evaporator section in fluid communication with said condenser section; and
   (iii) at least a second evaporator section in fluid communication with said condenser section;
(b) refrigerant contained in said heat pipe;
(c) at least a first liquid flow path leading a first portion of liquid refrigerant condensed in said condenser section to said first evaporator section; and
(d) at least a second liquid flow path leading a second portion of liquid refrigerant condensed in said condenser section to said second evaporator section, wherein said second evaporator section comprises a reservoir holding liquid refrigerant at a location different than said first evaporator section, wherein said second evaporator section has a total volume that is about 70% or less, or about 60% or less, or about 50% or less, or about 40% or less than the volume of the first evaporator section.
   For the purpose of convenience, heat pipes according to this paragraph are referred to herein as Heat Pipe 4.

The present invention provides printed circuit boards (PCB) comprising:
(a) at least a first heat generating component mounted to the PCB at a first location;
(b) at least a second heat generating component mounted to the PCB at a second location different than said first location; and
(c) at least one heat pipe comprising a closed pipe comprising:
   (i) a condenser section in thermal communication with cooling fluid located outside of said heat pipe,
   (ii) a first evaporator section comprising a first reservoir containing liquid refrigerant in heat transfer contact with said first heat generating component;
   (iii) a first liquid flow path leading a first portion of liquid refrigerant condensed in said condenser section to said reservoir in said first evaporator section;
   (iii) at least a second evaporator section comprising a second reservoir at a location along said heat pipe different than said first reservoir and containing a second portion of liquid refrigerant in heat transfer contact with said at least said second heat generating component; and
   (iv) at least a second liquid flow path leading said second portion of liquid refrigerant condensed in said condenser section to said reservoir in said second evaporator section.
      For the purpose of convenience, PCBs according to this paragraph are referred to herein as PCB 1.

The present invention provides printed circuit boards (PCB) comprising:
(a) at least a first heat generating component mounted to the PCB at a first location;
(b) at least a second heat generating component mounted to the PCB at a second location different than said first location; and
(c) a heat pipe comprising a closed pipe comprising:
   (i) a condenser section in thermal communication with cooling fluid located outside of said heat pipe and in which vaporous refrigerant is condensed to liquid refrigerant;
   (ii) a first evaporator section comprising a first reservoir containing liquid refrigerant in heat transfer contact with said first heat generating component, wherein the force of gravity provides at least a portion of the force returning liquid refrigerant condensed in said condenser section to said first evaporator section;
   (iii) at least a first liquid flow path leading a first portion of liquid refrigerant condensed in said condenser section to said reservoir in said first evaporator section;
   (iii) at least a second evaporator section comprising a second reservoir at a location along said heat pipe different than said first reservoir and containing a second portion of liquid refrigerant in heat transfer contact with said at least said second heat generating component, wherein the force of gravity provides at least a portion of the force returning liquid refrigerant condensed in said condenser section to said second evaporator section; and
   (iv) at least a second liquid flow path leading said second portion of liquid refrigerant condensed in said condenser section to said reservoir in said second evaporator section.
      For the purpose of convenience, PCBs according to this paragraph are referred to herein as PCB 2.

The present invention provides printed circuit boards (PCB) comprising:
(a) at least a first heat generating component mounted to the PCB at a first location;
(b) a second heat generating component mounted to the PCB at a second location above said first location;
(c) at least a third heat generating component mounted to the PCB at a third location above said first location; and
(d) a heat pipe comprising a closed pipe comprising:
   (i) a condenser section in thermal communication with cooling fluid located outside of said heat pipe and in which vaporous refrigerant is condensed to liquid refrigerant;
   (ii) a first evaporator section located below said condenser section and comprising a first reservoir containing liquid refrigerant in heat transfer contact with said first heat generating component, wherein the force of gravity provides at least a portion of the force returning liquid refrigerant condensed in said condenser section to said first evaporator section;
   (iii) at least a first liquid flow path leading a first portion of liquid refrigerant condensed in said condenser section to said reservoir in said first evaporator section;
   (iii) a second evaporator section comprising a second reservoir at a location along said heat pipe above said first reservoir and containing a second portion of liquid refrigerant in heat transfer contact with said second heat generating component, wherein the force of gravity provides at least a portion of the force returning liquid refrigerant condensed in said condenser section to said second evaporator section;
   (iv) at least a second liquid flow path leading said second portion of liquid refrigerant condensed in said condenser section to said reservoir in said second evaporator section;
   (v) at least a third evaporator section comprising a third reservoir at a location along said heat pipe above said first reservoir and containing a third portion of liquid refrigerant in heat transfer contact with said third heat generating component, wherein the force of gravity provides at least a portion of the force returning liquid refrigerant condensed in said condenser section to said third evaporator section; and
   (vi) at least a third liquid flow path leading said third portion of liquid refrigerant condensed in said condenser section to said reservoir in said third evaporator section.
      For the purpose of convenience, PCBs according to this paragraph are referred to herein as PCB 3.

The present invention provides printed circuit boards (PCB) comprising:
(a) at least a first heat generating component mounted to the PCB at a first location;
(b) at least a second heat generating component mounted to the PCB at a second location different than said first location; and
(c) at least one heat pipe comprising a closed pipe comprising:
   (i) a condenser section in thermal communication with cooling fluid located outside of said heat pipe,
   (ii) a first evaporator section comprising a first reservoir containing liquid refrigerant in heat transfer contact with said first heat generating component;
   (iii) a first liquid flow path leading a first portion of liquid refrigerant condensed in said condenser section to said reservoir in said first evaporator section;
   (iii) at least a second evaporator section comprising a second reservoir at a location along said heat pipe different than said first reservoir and containing a second portion of liquid refrigerant in heat transfer contact with said at least said second heat generating component, wherein said second evaporator section has a total volume that is about 70% or less, or about 60% or less, or about 50% or less, or about 40% or less than the volume of the first evaporator section; and
   (iv) at least a second liquid flow path leading said second portion of liquid refrigerant condensed in said condenser section to said reservoir in said second evaporator section.
      For the purpose of convenience, PCBs according to this paragraph are referred to herein as PCB 4.

The present invention provides methods of transferring heat comprising: heat pipe of the type which has a condenser section in which gaseous refrigerant is condensed to produce liquid refrigerant comprising:
(a) providing a closed heat pipe comprising:
   (i) a condenser section in heat transfer communication with a heat sink located outside the heat pipe,
   (ii) a first evaporator section in fluid communication with said condenser section and comprising a first reservoir containing liquid refrigerant; and
   (iii) at least a second evaporator section in fluid communication with said condenser section and comprising a second reservoir containing liquid refrigerant;
   (iv) at least a first liquid flow path leading from said condenser section to said first reservoir; and
   (v) at least a second liquid flow path leading from said condenser section to said second reservoir;
(b) cooling a first component or device by thermal contact with said liquid refrigerant in said first reservoir to produce refrigerant vapor that travels to said condenser section;
(c) cooling a second component or device by thermal contact with said liquid refrigerant in said second reservoir to produce refrigerant vapor that travels to said condenser section; and
(d) condensing refrigerant vapor in the condenser section to produce condensed liquid refrigerant and returning via said first liquid flow path a first portion of said condensed liquid refrigerant to said first reservoir and returning via said second liquid flow path a second portion of said condensed liquid refrigerant to said second reservoir.
   For the purpose of convenience, heat transfer methods according to this paragraph are referred to herein as Heat Transfer Method 1.

The present invention provides methods of transferring heat comprising:
(a) providing a closed heat pipe comprising:
   (i) a condenser section in heat transfer communication with a heat sink located outside the heat pipe and in which vaporous refrigerant is condensed to liquid refrigerant,
   (ii) a first evaporator section in fluid communication with said condenser section and comprising a first reservoir containing liquid refrigerant;
   (iii) a second evaporator section in fluid communication with said condenser section and comprising a second reservoir containing liquid refrigerant;
   (v) at least a first liquid flow path leading at least a portion of said condensed liquid refrigerant from said condenser section to said first reservoir wherein the force of gravity provides at least a portion of the force returning liquid refrigerant condensed in said condenser section to said first evaporator section;
   (vi) at least a second liquid flow path leading at least a portion of liquid refrigerant from said condenser section to said second reservoir wherein the force of gravity provides at least a portion of the force returning liquid refrigerant condensed in said condenser section to said second evaporator section;
(b) cooling a first component or device by thermal contact with said liquid refrigerant in said first reservoir to produce refrigerant vapor that travels to said condenser section;
(c) cooling at least a second component or device by thermal contact with said liquid refrigerant in said second reservoir to produce refrigerant vapor that travels to said condenser section; and
(e) condensing refrigerant vapor in the condenser section to produce said condensed liquid refrigerant.
   For the purpose of convenience, heat transfer methods according to this paragraph are referred to herein as Heat Transfer Method 2.

The present invention provides methods of transferring heat comprising:
(a) providing a closed heat pipe comprising:
   (i) a condenser section in heat transfer communication with a heat sink located outside the heat pipe and in which vaporous refrigerant is condensed to liquid refrigerant,
   (ii) a first evaporator section in fluid communication with said condenser section and comprising a first reservoir containing liquid refrigerant;
   (iii) a second evaporator section in fluid communication with said condenser section and comprising a second reservoir containing liquid refrigerant;
   (iv) at least a third evaporator section in fluid communication with said condenser section and comprising a third reservoir containing liquid refrigerant;
   (v) at least a first liquid flow path leading at least a portion of said condensed liquid refrigerant from said condenser section to said first reservoir wherein the force of gravity provides at least a portion of the force returning liquid refrigerant condensed in said condenser section to said first evaporator section;
   (vi) at least a second liquid flow path leading at least a portion of liquid refrigerant from said condenser section to said second reservoir wherein the force of gravity provides at least a portion of the force returning liquid refrigerant condensed in said condenser section to said second evaporator section;
   (vii) at least a third liquid flow path leading liquid refrigerant from said condenser section to said third reservoir wherein the force of gravity provides at least a portion of the force returning liquid refrigerant condensed in said condenser section to said third evaporator section;
(b) cooling a first component or device by thermal contact with said liquid refrigerant in said first reservoir to produce refrigerant vapor that travels to said condenser section;
(c) cooling at least a second component or device by thermal contact with said liquid refrigerant in said second reservoir to produce refrigerant vapor that travels to said condenser section;
(d) cooling at least a third component or device by thermal contact with said liquid refrigerant in said third reservoir to produce refrigerant vapor that travels to said condenser section; and
(e) condensing refrigerant vapor in the condenser section to produce said condensed liquid refrigerant.
   For the purpose of convenience, heat transfer methods according to this paragraph are referred to herein as Heat Transfer Method 3.

The present invention provides methods of transferring heat comprising: heat pipe of the type which has a condenser section in which gaseous refrigerant is condensed to produce liquid refrigerant comprising:
(a) providing a closed heat pipe comprising:
   (i) a condenser section in heat transfer communication with a heat sink located outside the heat pipe,
   (ii) a first evaporator section in fluid communication with said condenser section and comprising a first reservoir containing liquid refrigerant; and
   (iii) at least a second evaporator section in fluid communication with said condenser section and comprising a second reservoir containing liquid refrigerant, wherein said second evaporator section has a total volume that is about 70% or less, or about 60% or less, or about 50% or less, or about 40% or less than the volume of the first evaporator section;
   (iv) at least a first liquid flow path leading from said condenser section to said first reservoir; and
   (v) at least a second liquid flow path leading from said condenser section to said second reservoir;
(b) cooling a first component or device by thermal contact with said liquid refrigerant in said first reservoir to produce refrigerant vapor that travels to said condenser section;
(c) cooling a second component or device by thermal contact with said liquid refrigerant in said second reservoir to produce refrigerant vapor that travels to said condenser section; and
(d) condensing refrigerant vapor in the condenser section to produce condensed liquid refrigerant and returning via said first liquid flow path a first portion of said condensed liquid refrigerant to said first reservoir and returning via said second liquid flow path a second portion of said condensed liquid refrigerant to said second reservoir.
   For the purpose of convenience, heat transfer methods according to this paragraph are referred to herein as Heat Transfer Method 4.

### BRIEF DESCRIPTION OF THE DRAWINGS

Figure A is a schematic representation of a gravity-return-return heat pipe.

Figure B is a schematic representation of a capillary-return heat pipe.

Figure C is a schematic representation of a printed circuit board containing three heat generating components.

FIG. 1 is a schematic representation of a heat pipe according to one embodiment of the present invention.

FIG. 1A is a schematic representation of the cross section of the heat pipe used in Example 1.

FIG. 1B is a schematic representation of the cross section of the heat pipe used in Example 1.

Figure C1 is a schematic representation of a heat pipe representative of prior heat pipes.

Figure C2 is a schematic representation of the cross section of the heat pipe used in Comparative Example 1.

Figure C3 is a schematic representation of the cross section of the heat pipe used in Comparative Example 2.

Figure C4 is a schematic representation of the cross section of the heat pipe used in Comparative Example 3.

FIG. 2 is a schematic representation of a heat pipe according to one embodiment of the present invention.

FIG. 2A is a schematic representation of a heat pipe according to one embodiment of the present invention and whose performance is described in Example 2A.

FIG. 2B is a schematic representation of a heat pipe according to one embodiment of the present invention and whose performance is described in Example 2B.

FIGS. 3A through 3F are schematic representations of heat pipes according to embodiments of the present invention.

FIG. 4 is a photograph of a heat pipe according to embodiments of the present invention and a heat pipe not within the scope of the invention.

### DETAILED DESCRIPTION

Applicants have unexpectedly found that the needs and advantages mentioned above, among others, can be achieved, and/or that cooling efficiency and effectiveness at low cost can be obtained, by use of heat pipes, devices, systems and/or methods as described herein.

### Heat Pipes

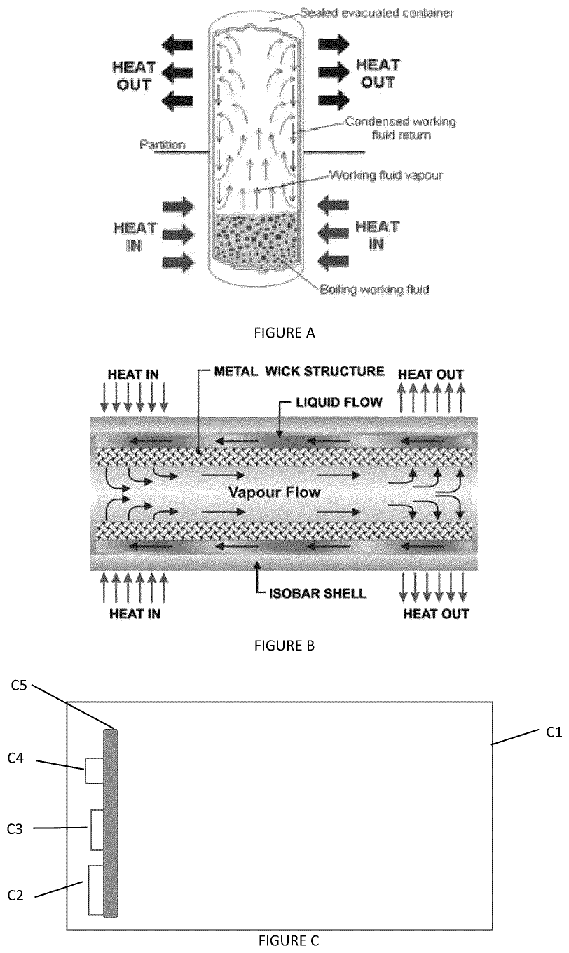

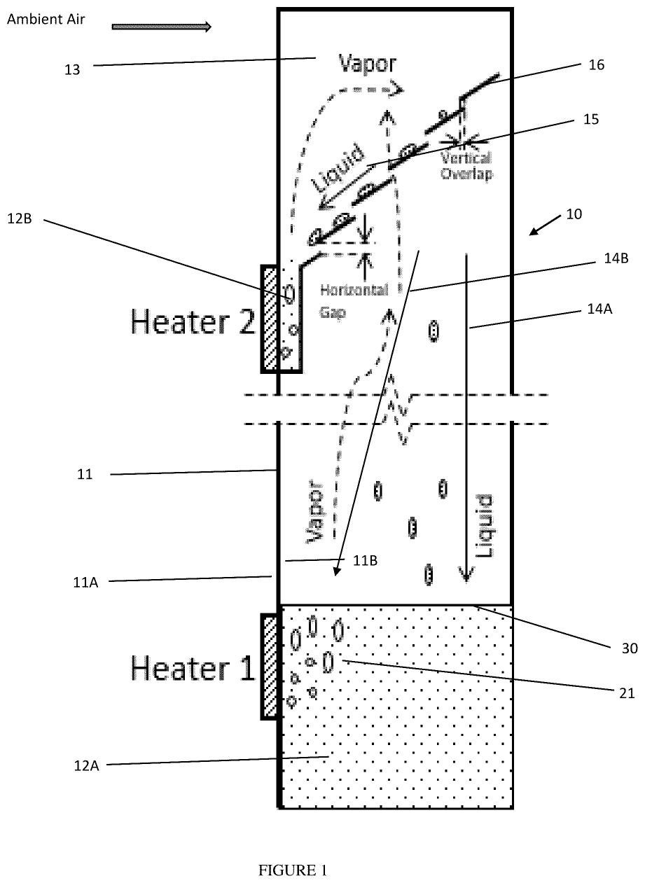

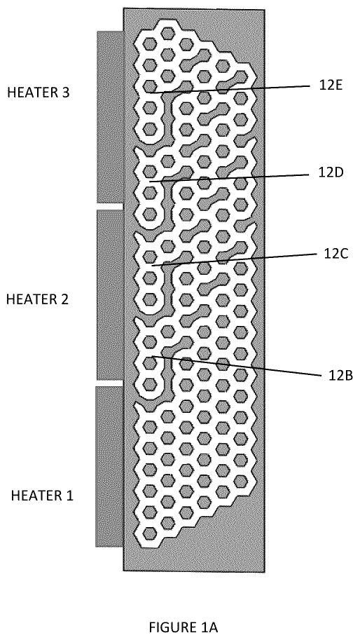

The present invention includes heat pipes that provide excellent thermal performance and in preferred embodiments the ability to cool efficiently and effectively at least two sources of heat located at different locations. By way of example, reference is made to FIG. 1 hereof which shows schematically the cross section of a heat pipe, generally indicated at 10. Although heat pipe 10 is shown schematically as having a rectangular cross section, those skilled in the art will appreciate that a wide variety of internal and external shapes and dimensions can be used consistent with the teaching hereof, and all such shapes and dimensions are within the scope of the present invention.

The heat pipe 10 preferably comprises a contained area bounded by pipe wall(s) 11 comprising a pipe wall outer surface 11A and a pipe wall inner surface 11B. The heat pipe includes a first evaporator section 12A located at one end of the heat pipe and a condenser section 13 located at the opposite end of the heat pipe. It will be appreciated that while the evaporator section 12A is illustrated as being at one end of the heat pipe and the condenser section is illustrated as being at the other end of the heat pipe, it is not necessary according to the present invention that the sections be located at either end of the heat pipe.

The heat pipe 10 includes at least a second evaporator section 12B located intermediate to the condenser section and the first evaporator section. Once again, those skilled in the art will appreciate that while the heat pipe 10 illustrated FIG. 1 is shown as having substantially straight sidewalls, and therefore evaporator section 12B is located above the first evaporator section 12A and below the condenser section 13, this arrangement is not necessarily required. For the configuration illustrated in FIG. 1, the top of the first evaporator section 12A is represented by the horizontal line 30 located at approximately 30 volume percent of the heat pipe, but it will be appreciated by those skilled in the art that this location is for the purposes of illustration and not necessarily by way of limitation. Furthermore, the line 30 represents the approximate liquid level in the heat pipe when the heat pipe is not in operation, which is referred to herein as the charge level, but it will be appreciated that in operation the liquid level may not correspond to this location. In operation, heat would be transferred from a first heat source (Heater 1) through the pipe wall 11 and into the reservoir of liquid refrigerant in the first evaporator section 12A to produce refrigerant vapour, which is shown as refrigerant bubbles 21 in FIG. 1 and which flows generally upward to the condenser section 13.

In the condenser section 13, the outer surface of the heat pipe is exposed to the relatively cool temperature of a heat sink (for example, ambient air blown across the top of the heat pipe as illustrated schematically in FIG. 1) which cools and condenses the refrigerant vapour in contact with the inner surface 11B of the heat pipe wall 11 in condenser section 13. A first portion of the condensed refrigerant liquid follows a first flow path, generally indicated as path 14A for example, to return to the reservoir contained in the first evaporator section 12A. It will be appreciated by those skilled in the art than multiple flow paths leading from the condenser section to the evaporator section 12A will exist in many heat pipe configurations according to the present invention, and flow path 14A is shown as only one general flow path that may exist. Another possible flow path may include the general path as indicated as 14B. Thus, while it is contemplated that numerous and varied flow paths may be taken by this at least first portion of the refrigerant liquid on its return to the first evaporator section, the first flow path simply can comprise a series of liquid droplets falling under the influence of gravity from the condenser section 13 to the first evaporator section 12A.

An important and critical aspect of the present invention is the provision of a second flow path, indicated generally as item 15 for example, which leads or directs at least a second portion of the refrigerant liquid which is condensed in the condenser section 13 to flow to the reservoir contained in the evaporator section 12B. As those skilled in the art will appreciate, numerous features may be included in the heat pipe to capture and route a portion of the condensed liquid from the condenser section to the reservoir. One such feature may include, for example, a series of angled platforms, plates, tiles or the like 16 located in the general flow path taken by liquid refrigerant as it falls from the condenser section 13 under the influence of gravity. These platforms or plates are located and angled to cause such droplets to flow toward the inner wall of the heat pipe and into the reservoir contained in the second evaporator section 12B. In preferred embodiments, small gaps between adjacent platforms, plates or the like are preferably included in order to allow some upward passage of the refrigerant vapour. In addition, the lower edge of each plate is preferably aligned to overlap with the upper edge of the next flow plate, platform and the like in the direction of liquid flow. Given the teachings contained in the present application, those skilled in the art will be able to select the extent of both vertical separation and the extent of vertical overlap to achieve the desired flow of refrigerant into the reservoir of the evaporator section 12B and the desired level refrigerant vapour flow for each individual application. In this way, the desired supply of liquid refrigerant is provided at a point intermediate of the first evaporator section and the condenser section, and in preferred embodiments the second evaporator section is located proximate to a heat source to be cooled, for example, Heater 2 in FIG. 1, thus providing exceptional cooling to such second heat source since it will be cooled by phase change heat transfer of the refrigerant, which is much more effective and efficient than the heat transfer from the second heat source which might have occurred according to prior heat pipe configurations.

Those skilled in the art will appreciate that while FIG. 1 discloses a gravity driven heat pipe, the present invention is readily adaptable for use with heat pipes having other forces, or multiple forces, driving the return of condensed liquid in the general direction of the first evaporator section. Accordingly, the present invention includes heat pipes having any one or combination of liquid refrigerant driving forces described hereinabove, including particularly in preferably capillary return heat pipes and gravity/capillary return heat pipes.

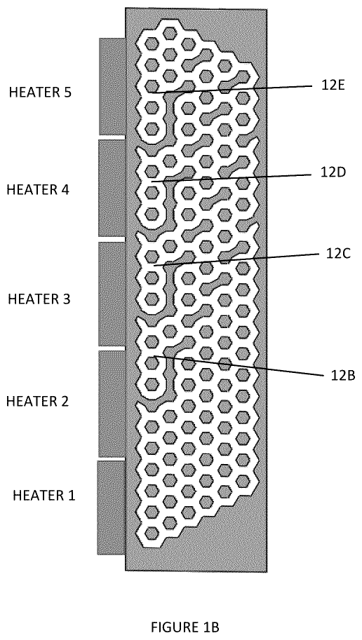

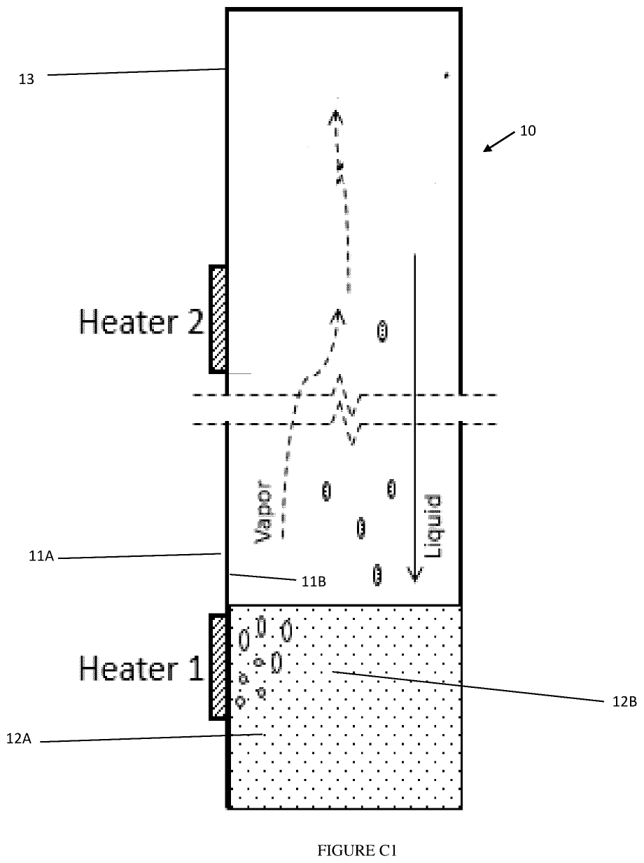

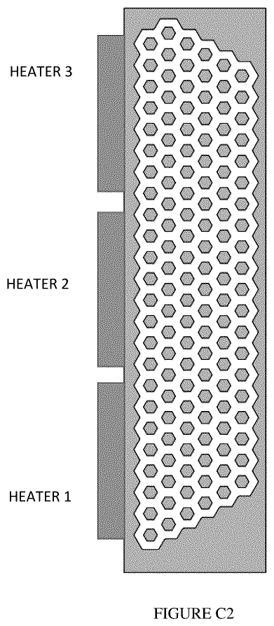

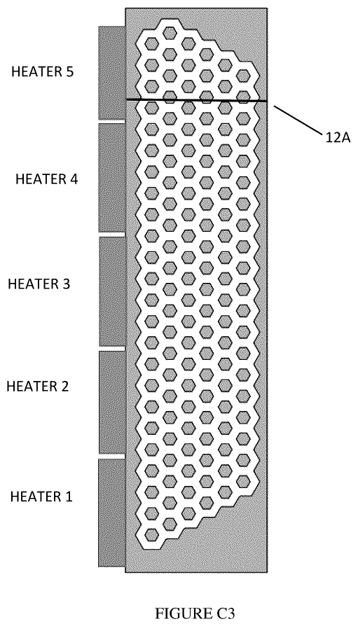

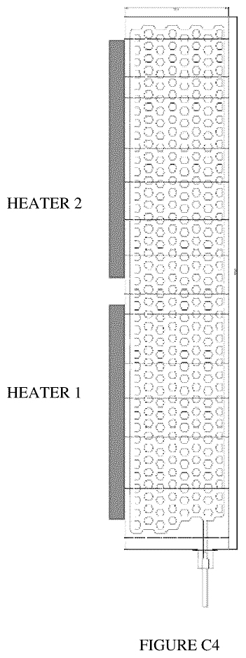

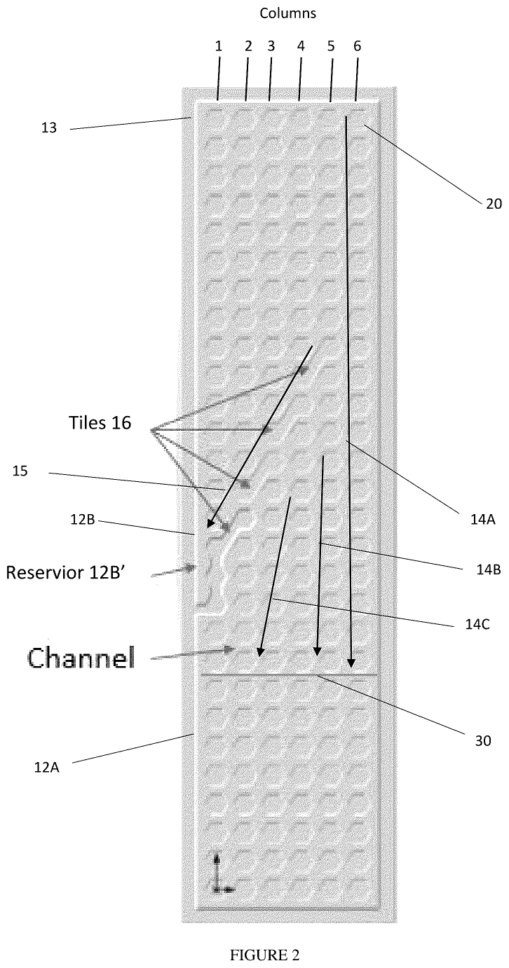

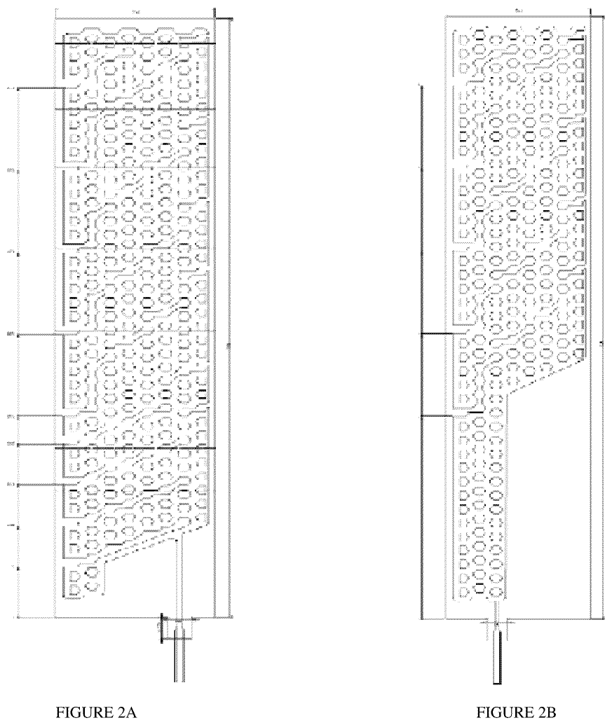

FIG. 2 depicts a heat pipe 10 having a generally honeycomb grid pattern of hexagonal cells for allowing free upward flow of refrigerant vapour from the bottom region of the heat pipe, which will generally contain the first evaporator section 12A, to the condenser section 13. The top of the first evaporator section 12A is represented generally by the horizontal line located at approximately 30 volume percent of the heat pipe. In operation, heat would be transferred from a heat source (not shown) through the pipe wall and into the reservoir of liquid refrigerant in the first evaporator section 12A. Refrigerant vapor is generated and flows upward through the open vertical and diagonal channels in the heat pipe, that is, channels that are not blocked by one or more of the tiles 16, to the condenser section 13. In the condenser section 13, the outer surface of the heat pipe is exposed to the relatively cool temperature of a heat sink (for example, ambient air) which cools and condenses the refrigerant vapour in contact with the inner surface of the heat pipe wall in condenser section 13. A first portion of the condensed refrigerant liquid follows a first flow path, such as for example 14A, to return to the reservoir contained in the first evaporator section 12A. As mentioned above, alternative and/or additional flow paths could also be followed by the liquid refrigerant in returning to the first evaporator section 12A, such as flow paths 14B and 14C for example. Thus, while it is contemplated that numerous and varied flow paths may be taken by this first portion of the refrigerant liquid on its return to the first evaporator section 12A, the first flow path simply can comprise a series of liquid droplets falling under the influence of gravity from the condenser section 13 to the first evaporator section 12A through one or more open channels, such as exits for example between Column 5 and 6 and the lower portion between Column 4 and 5, and many other potential channels, including but not limited to those represented by flow paths 14B and 14C.

An important and critical aspect of the present invention is the provision of at least a second flow path, indicated generally in FIG. 2 as item 15, which directs at least a second portion of the refrigerant liquid which is condensed in the condenser section 13 to flow to the reservoir 12B′ contained in the evaporator section 12B. As those skilled in the art will appreciate, numerous structures may be included in the heat pipe to capture and route a portion of the condensed liquid from the condenser section to the reservoir. One such structure may include, for example a series of angled platforms, plates, tiles or the like 16 located in the general flow path taken by liquid refrigerant as it falls from the condenser section 13 under the influence of gravity generally along flow path 14. These platforms or plates are preferably located and angled, otherwise configured, to cause such droplets to flow toward the inner wall of the heat pipe and into the reservoir 12B′ contained in the second evaporator section 12B. In preferred embodiments, small vertical gaps are included between the platforms or plates in order to allow some upward passage of the refrigerant vapour, and small vertical overlap between adjacent platforms or plates are included to help direct the liquid refrigerant along the desired flow path into the reservoir of the evaporator section 12B. In this way, the desired supply of liquid refrigerant is provided to at least one point intermediate of the first evaporator section and the condenser section, an in preferred embodiments a second heat source (not shown) can be located in the vicinity of this second evaporator section, thus providing exceptional cooling performance to the heat pipes of the present invention, especially and preferably when a second heat source is present since it will be cooled by phase change heat transfer of the refrigerant, which is much more effective and efficient than the heat transfer which might have occurred according to prior heat pipe configurations.

Thus, in a preferred aspect of the present heat pipes, including Heat Pipes 1-4, the interior of the heat pipe includes a honeycomb grid that is not fully homogeneous but instead includes a series of modifications to the grid structure, such as for example as one or more angled tiles, plates, platforms or similar obstructions formed into the grid structure, that tend to direct at least a portion of the condensed refrigerant liquid along a flow path leading to the second evaporator section. For example, such exemplary structures are arranged to form a flow path or channel leading a portion of the condensed liquid refrigerant to the second evaporator section. In particular the general honeycomb patter disclosed in FIG. 2 includes six (6) columns of hexagonal cells or islands 20 around which the liquid will generally flow downward, with the space between the columns of cells allowing for generally downward flow of liquid and upward flow of vapour. For example, liquid flowing from above Rows 5 and 6 would be able to flow to the bottom of the heat pipe to the first evaporator section. If all the rows and spaces were substantially the same as per the prior heat pipes, all of the liquid would flow in this fashion to the first evaporator section at the bottom of the heat pipe. However, according to embodiments of the present invention, several of the rows are interrupted by overlapping and angled tiles or plates built into the honeycomb structure. For example, some portion of the liquid refrigerant flowing down between columns 4 and 5 in FIG. 2 will encounter the angled tile or plate at in the 9^{th} row of cells, thus diverting at least a portion of the refrigerant liquid toward a side of the heat pipe above the first evaporator section to where a second reservoir is located to hold the selected amount of liquid refrigerant in heat transfer contact with the inner surface of the heat pipe, preferably adjacent to a second heat source.

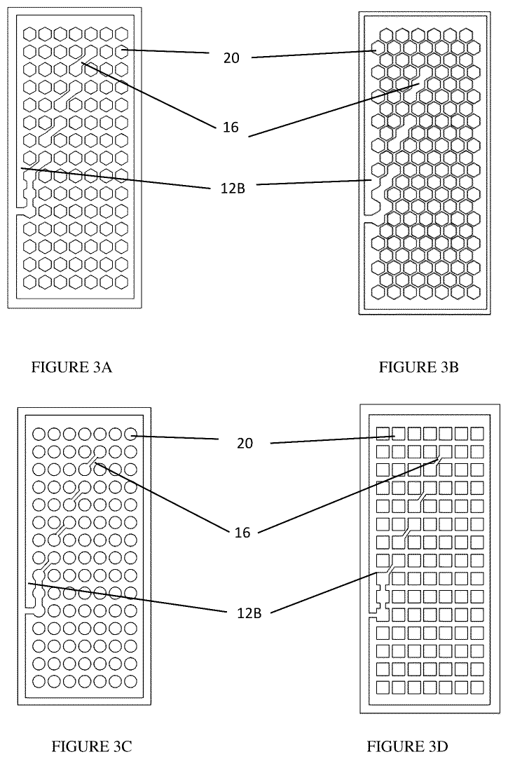

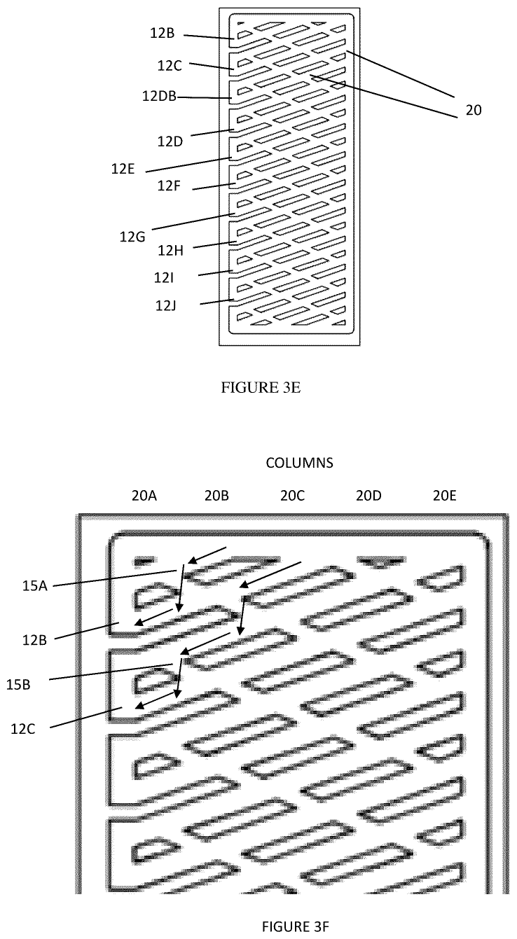

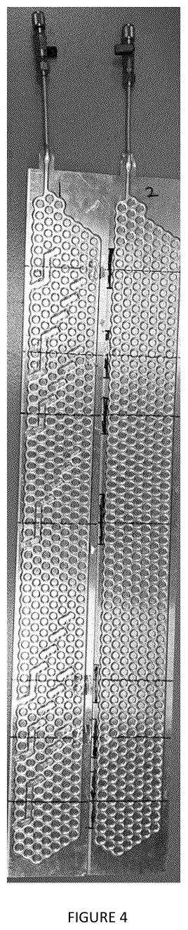

Alternative heat pipe configurations with different shapes and sizes for the cells or islands, the vapour channels, the tiles or platforms and the reservoirs are illustrated in each of FIGS. 3A-3E.

In FIG. 3A, rows of hexagonal cells 20 aligned in what is known as a rectangular grid arrangement wherein each cells in a row is vertically aligned and each cell in an column is horizontally aligned, and including a series of angled plates or tiles 16 to channel a portion of the condensed refrigerant fluid to a reservoir in an intermediate evaporator 12B.

In FIG. 3B, rows of hexagonal cells 20 aligned in what is known as a honeycomb grid arrangement, and with a series of angled plates or tiles 16 are used to channel a portion of the condensed refrigerant fluid to a reservoir in an intermediate evaporator 12B.

In FIG. 3C, rows of circular cells 20 with a series of angled plates or tiles 16 are used to channel a portion of the condensed refrigerant fluid to a reservoir in an intermediate evaporator 12B.

In FIG. 3D, rows of square cells 20 with a series of angled plates or tiles 16 are used to channel a portion of the condensed refrigerant fluid to a reservoir in an intermediate evaporator 12B.

In FIG. 3E, columns of angled and overlapping rectangular cells 20, some of which are truncated as explained below in connection with FIG. 3F, are used to create a flow path leading condensed refrigerant fluid to several intermediate reservoirs in intermediate evaporator sections. As can be seen in this embodiment, the angled rectangular cells provide the ledges, tiles, plates or the like to provide the necessary intermediate refrigerant flow paths, as explained in more detail in connection with FIG. 3F.

FIG. 3F provides a blown up view of the top portion of the heat pipe shown in FIG. 3E, the five columns of angled rectangular cells 20 are labelled from left to right as columns 20A-20E used to create a flow path leading condensed refrigerant fluid to several intermediate reservoirs in intermediate evaporator sections. As can be seen, the rows 20A and 20E are at the left and right sides of heat pipe, and each of these rectangular cells is partially truncated along the left and right edges, respectively. In operation, most of the refrigerant condensed in the top of the heat pipe between rows 20A and 20B, and some of the refrigerant condensed above rows 20B and 20C, will tend to follow the flow path 15A into the reservoir of evaporator 12B. Similarly, most of the refrigerant condensed in the top of the heat pipe between rows 20B and 20C, and some of the refrigerant condensed above rows 20C and 20D, will tend to follow the flow path 15B into the reservoir of evaporator 12C. Given these descriptions, those skilled in the art will appreciate that the configuration in FIG. 3E provides a series of multiple flow paths leading to a series of intermediate evaporation sections 12B-12J.

Although it is contemplated that the tiles and plates used in the heat pipes of the present invention, including each of Heat Pipes 1-4 and the heat pipes included in each of PCBs 1-4 and Heat Transfer Methods 1-4, may be angled over a wide variety of angles, in preferred embodiments the tiles have an angle of about 10° to about 70° relative to a plane normal to the general direction of flow of refrigerant liquid from the condenser section to the first evaporator section, which is relative to the horizontal in many applications involving gravity return heat pipe.

The present invention includes tiles and plates used in the heat pipes of the present invention, including each of Heat Pipes 1-4 and the heat pipes included in each of PCBs 1-3 and Heat Transfer Methods 1-4, at an angle of about 20° to about 50° relative to a plane normal to the general direction of flow of refrigerant liquid from the condenser section to the first evaporator section, which is relative to the horizontal in many applications involving gravity return heat pipe. In preferred embodiments of Heat Pipe 4, and Heat Transfer Method 4, and PCB 4, the second evaporator section does not include any flow paths or channels leading to another evaporator section, as illustrated in FIG. 2B.

Although it is contemplated that the charge ratio used in the heat pipes of the present invention, including each of Heat Pipes 1-4 and the heat pipes included in each of PCBs 1-4 and Heat Transfer Methods 1-4, may vary widely, in preferred embodiments the charge ratio is from about 20% to about 90% by volume.

The charge ratio used in the heat pipes of the present invention, including each of Heat Pipes 1-4 and the heat pipes included in each of PCBs 1-4 and Heat Transfer Methods 1-4, in preferred embodiments is in the range of from about 20% to about 60% by volume.

### Devices and Systems

The present invention includes devices and systems, including each of PCB1 through PCB4, that require cooling during operation.

The present invention includes telecommunication devices and systems that include printed circuit boards, including each of PCB1 through PCB4.

The present invention includes telecommunication devices and systems that include printed circuit boards, including each of PCB1 through PCB4, that include a 5G chip.

The present invention includes a 5G chip cooled by heat pipe of the present invention, including each of Heat Pipes 1 through 4.

The present invention includes a systems or device that comprises a heat pipe of the present invention, including each of Heat Pipes 1 through Heat Pipes 4.

### Methods

The present invention includes methods for cooling a device or system or a component of a device or system using the methods of the present invention, including each of Heat Transfer Method 1 through Heat Transfer Method 4.

The present invention includes methods for cooling telecommunication devices or systems using the methods of the present invention, including each of Heat Transfer Method 1 through Heat Transfer Method 4.

The present invention includes methods for cooling telecommunication devices or systems using the methods of the present invention, including each of Heat Transfer Method 1 through Heat Transfer Method 4.

The present invention includes methods of cooling telecommunication devices and systems that include a 5G chip using the methods of the present invention, including each of Heat Transfer Method 1 through Heat Transfer Method 4.

The present invention includes methods of cooling at least a portion of a printed circuit board comprising contacting at least a portion of said printed circuit board with a heat pipe of the present invention, including each of Heat Pipe 1 through Heat Pipe 4.

The present invention includes methods of cooling at least a portion of a printed circuit board comprising a 5G chip by contacting said 5G chip with a heat pipe of the present invention, including each of Heat Pipe 1 through Heat Pipe 5.

### EXAMPLES

### Comparative Examples 1A-1F

A heat pipe corresponding generally to Figure C1 hereof was formed from two aluminum plates, except that instead of two heaters as shown in Figure C1, a total of three heater bands were used. Each of the three heaters had a power of 13.33 watts to produce a total power of 40 watts. The arrangement of this example simulates, for example, the situation that would exist if there were three components to be cooled and arranged vertically at these locations on a printed circuit board. A thermocouple was provided at a location on the heat pipe wall at the following locations measured vertically from the bottom of the heat pipe: 70 mm, 150 mm, 210 mm, 270 mm and 330 mm.

Six different heat pipe charge ratios were tested using the heat pipe configuration described in the example, as indicated in Table C1 below.

As shown in Figure C2, the cross section of the heat pipe illustrates that the channel between the two aluminum plates has a substantially uniform honeycomb configuration, and as a result, during operation the working fluid R-1233zd (E) contained in the reservoir of the evaporation section is heated, vaporizes and flows generally upward through the heat pipe to the condenser section. As the working fluid is condensed in the condenser section, it flows just generally downward back to the evaporator section which contains the liquid working fluid. The heat pipe was operated at a room temperature of about 23.7° C., and at equilibrium the temperatures that were measured are reported in Table C1 below:

TABLE C1

| | | Temperature, ° C. | | | | | | |
|---|---|---|---|---|---|---|---|---|
| | Charge | | | | | | Average | Max temperature- |
| Comparative | Ratio, | Vertical Position/mm | | | | | temperature, | Min temperature, |
| Example No. | Vol % | 70 | 150 | 210 | 270 | 330 | ° C. | ° C. |
| C1A | 95 | 67.4 | 66.4 | 74.0 | 72.8 | 75.3 | 71.2 | 8.9 |
| C1B | 80 | 65.4 | 64.6 | 71.7 | 68.8 | 69.6 | 68.0 | 7.1 |
| C1C | 60 | 64.7 | 63.7 | 67.0 | 67.3 | 74.1 | 67.4 | 10.4 |
| C1D | 55 | 64.1 | 65.0 | 67.7 | 68.9 | 73.6 | 67.9 | 9.5 |
| C1E | 50 | 66.7 | 66.4 | 68.8 | 72.5 | 74.9 | 69.8 | 8.5 |
| C1F | 45 | 67.7 | 66.4 | 71.7 | 74.4 | 76.5 | 71.3 | 10.1 |

As can be seen from the data reported in Table C1, the charge ratio that produces the lowest average temperature during operation was 60% (Example C1C), and the charge ratio that produced the smallest temperature differential was 80% (Example C1B).

### Examples 1A-1F

A heat pipe having the same overall dimensions and the same heaters and thermocouples as described in Comparative Example 1 is formed, except that the cross section of the heat pipe was generally as described in connection with FIG. 1 and specifically as illustrated FIG. 1A. Six different heat pipe charge ratios were tested using the heat pipe configuration described in the example, as indicated in Table 1 below.

As shown in FIG. 1A, the cross section of the heat pipe illustrates that the channel between the two aluminum plates has a honeycomb configuration that captures and routes a portion of the condensed liquid from the condenser section to the reservoir in each of evaporator sections 12B-12E. As refrigerant is condensed in the condenser section, a portion of the condensed working fluid liquid flows downward to each of the evaporator sections 12B-12E.

The heat pipe was operated at a room temperature of about 23.7° C. and at equilibrium, the temperatures that were measured are reported in Table 1 below, together with the results from Comparative Example 1:

TABLE 1

| | Examples 1A-1F | | | | | | | Comparative Examples C1A-C1F | | | | | | |
|---|---|---|---|---|---|---|---|---|---|---|---|---|---|---|
| | | | | | | Avg. | Max temp.- | | | | | | Avg. | Max temp.- |
| ChrgRatio | Vertical Position* | | | | | temp. | Min temp. | Vertical Position* | | | | | temp. | Min temp. |
| % | 1 | 2 | 3 | 4 | 5 | ° C. | ° C. | 1 | 2 | 3 | 4 | 5 | ° C. | ° C. |
| 95 | 68.4 | 70.1 | 72.9 | 69.2 | 68.6 | 69.8 | 4.5 | 67.4 | 66.4 | 74.0 | 72.8 | 75.3 | 71.2 | 8.9 |
| 80 | 67.3 | 66.7 | 66.9 | 65.9 | 66.6 | 66.7 | 1.5 | 65.4 | 64.6 | 71.7 | 68.8 | 69.6 | 68.0 | 7.1 |
| 60 | 64.8 | 64.6 | 64.3 | 62.3 | 65.2 | 64.3 | 2.9 | 64.7 | 63.7 | 67.0 | 67.3 | 74.1 | 67.4 | 10.4 |
| 55 | 65.5 | 65.1 | 63.7 | 62.7 | 65.0 | 64.4 | 2.8 | 64.1 | 65.0 | 67.7 | 68.9 | 73.6 | 67.9 | 9.5 |
| 50 | 65.1 | 63.8 | 64.4 | 64.5 | 63.4 | 64.2 | 1.7 | 66.7 | 66.4 | 68.8 | 72.5 | 74.9 | 69.8 | 8.5 |
| 45 | 66.4 | 65.3 | 66.1 | 66.7 | 66.0 | 66.1 | 1.4 | 67.7 | 66.4 | 71.7 | 74.4 | 76.5 | 71.3 | 10.1 |

*The verticle positions at 70 mm, 150 mm, 210 mm, 270 mm and 330 mm are designated in the table as positons 1-5, respectively.

As can be seen from the results reported in Table 1 above, the configuration according to the described embodiment of the present invention produced a lower average temperature and a smaller temperature difference for every charge ratio tested. Furthermore, the best performance form the prior heat pipe occurred at charge ratios of 80% as measured by average temperature and 60% as measured by temperature differential. In contrast, the best performance of the heat pipe of the present invention occurred at much lower charge ratios, that is, 50% for the lowest average temperature and the lowest temperature differential. Thus, this example illustrates that the heat pipe of the present invention provides at least three important advantages: (1) lower average temperature, which is a measure of cooling effectiveness; (2) smaller temperature differentials, which help to avoid unwanted temperature extremes in the heat pipe and hence improve operability and equipment life; and (3) reduced cost of working fluid by having a reduced charge ratio to achieve better performance.

### Comparative Example 2

A heat pipe corresponding generally to Figure C1 hereof was formed from two aluminum plates, except that instead of two heaters as shown in Figure C1, a total of five heater bands were used.

The heat pipe was approximately 935 mm from the bottom to the top, and the five heater bands were located approximately as indicated in Figure C3. Each heater has a power of 11 watts to produce a total power to the heat pipe of 55 watts. A thermocouple is provided at a location on the heat pipe wall at the following locations measured vertically from the bottom of the heat pipe: 100 mm, 460 mm, 600 mm, 740 mm and 880 mm. The arrangement of this example simulates, for example, the situation that would exist if there were five components to be cooled and arranged vertically at these locations on a printed circuit board. The charge ratio of the working fluid R1233zd (E) was set to approximately 90% given that heat input would be present along essentially the entire length of the heat pipe. This liquid level is shown approximately by line 12A when all heaters are turned off.

As shown in Figure C3, the cross section of the heat pipe illustrates that the channel between the two aluminum plates has a substantially uniform honeycomb configuration, and as result, during operation the working fluid R-1233zd (E) contained in the reservoir of the evaporation section is heated, vaporizes and flows generally upward through the heat pipe to the condenser section. As the working fluid is condensed in the condenser section, it flows just generally downward back to the evaporator section which contains the liquid working fluid. The heat pipe was operated at a room temperature of about 26.6° C., and at equilibrium the temperatures that were measured are reported in Table C2 below:

TABLE C2

| Vertical Position/mm | Temperature, ° C. |
|---|---|
| 880 | 49.2 |
| 740 | 49.8 |
| 600 | 50.2 |
| 460 | 51.3 |
| 100 | 47.4 |

This example shows that temperature of the heat pipe at the 100 mm location was 47.4° C., and the differential between the 100 mm location and the 460 mm location was 3.9° C., and this was the maximum measured temperature differential for the operating heat pipe.

### Example 2

A heat pipe having the same overall dimensions and the same heaters and thermocouples as described in Comparative Example 2 is formed, except that the cross section of the heat pipe was generally as described in connection with FIG. 1 and specifically as illustrated FIG. 1B. Because of the more efficient and effective configuration of a heat pipe of the present invention was used, the test was performed with a charge ratio of 40%, which is less than half the charge ratio that was used in Comparative Example 2. As seen in FIG. 1B, the structure between the two aluminum plates captures and routes a portion of the condensed liquid from the condenser section to the reservoir in each of evaporator sections 12B-12E. As refrigerant is condensed in the condenser section, a portion of the condensed working fluid liquid flows downward to each of the evaporator sections 12B-12E.

The heat pipe was operated at a room temperature of about 26.6° C. and at equilibrium, the temperatures that were measured are shown in Table 2 below, together with the results from Comparative Example 2:

TABLE 2

| | Temperature, ° C. | |
|---|---|---|
| | | Comparative |
| Vertical Position/mm | Example 2 | Example 2 |
| 880 | 47.9 | 49.2 |
| 740 | 48.0 | 49.8 |
| 600 | 49.3 | 50.2 |
| 460 | 48.6 | 51.3 |
| 100 | 45.5 | 47.4 |

As can be seen from the results reported in Table 2 above, the configuration according to the present invention produced a cooler temperature at each location along the heat pipe, indicating that for equivalent conditions more cooling is provided by the heat pipe according to the present invention even with a charge ratio that is less than one half the charge ratio used in Comparative Example 2. Furthermore, the temperature differential between sections of the heat pipe was lower for certain sections of the heat pipe compared to the prior heat pipe configuration. For example, the temperature increases by only 3.1° C. from the 100 mm location to the 460 mm location, whereas in the prior heat pipe configuration temperature increases 3.9° C., which indicates a superior level of cooling efficiency between those locations. This example this exhibits the same advantages described above in connection with Example 1.

### Comparative Example 3A

A heat pipe corresponding generally to Figure C1 hereof and specifically as in Figure C4 was formed from two aluminum plates and had two heat sources of the same size and heat generation, with Heater 1 being located adjacent to one side of the lower half of the heat pipe and Heater 2 being located adjacent to the same side but along the upper half of the heat pipe. A separate thermocouple was provided at each of seven locations on the heat pipe wall spaced approximately evenly apart from the bottom to the top of the heat pipe. The working fluid in the heat pipe was R1233zd (E), and the charge of R1233zd (E) required to provide the best performance in the heat pipe was determined to be 63.1 grams.

Additionally, a 1 mm aluminum plate was tested under the same operating conditions as used for the heat pipe. The results of these two tests are provided below:

| | Optimized | | | | | | | | | Maximum |
|---|---|---|---|---|---|---|---|---|---|---|
| | charging | | | | | | | | Average | temperature |
| | weight of | | | | | | | | temperature | raise |
| | R1233zd(E)/ | Temperature raise/° C. | | | | | | | raise/ | difference/ |
| Item | g | 1 | 2 | 3 | 4 | 5 | 6 | 7 | ° C. | ° C. |
| 1 mm | NA | 30.8 | 33.8 | 36.1 | 37.0 | 40.3 | 40.2 | 37.0 | 36.5 | 9.5 |
| aluminum | | | | | | | | | | |
| plate | | | | | | | | | | |
| C3 | 63.1 | 28.0 | 31.7 | 35.1 | 34.0 | 38.1 | 38.5 | 37.5 | 34.7 | 10.5 |

### Examples 2A and 2B

Two heat pipes having the same overall dimensions and the same heaters and thermocouples as described in Comparative Example 3 are formed, except that the cross section of the heat pipe was generally as described in connection with FIG. 1 and specifically as illustrated FIGS. 2A and 2B. In particular, the heat pipe shown in FIG. 2A had nine (9) evaporator sections and associated flow path channels, as indicated, in accordance with the present invention. The heat pipe of FIG. 2B had an upper section that was essentially configured as the upper section of the heat pipe of FIG. 2A, that is, the top five (5) evaporator sections and associated flow channels of each of the heat pipes of FIG. 2A and FIG. 2B were dimension and configured substantially the same, as shown. However, the bottom four (4) flow paths of the heat pipe of FIG. 2A were replaced by a single evaporator section according tot the heat pipe of FIG. 2B. Importantly, this single lower evaporator section was dimensioned to have a volume that was less than half of the total volume for the four lower evaporator sections of the heat pipe of FIG. 2A. The optimized charge and performance for the heat pipes of FIGS. 2A and 2B, together with the results repeated for Comparative Example 3, are reported in the Table below:

| | Optimized | | | | | | | | | Maximum |
|---|---|---|---|---|---|---|---|---|---|---|
| | charging | | | | | | | | Average | temperature |
| | weight of | | | | | | | | temperature | raise |
| | R1233zd(E)/ | Temperature raise/° C. | | | | | | | raise/ | difference/ |
| Item | g | 1 | 2 | 3 | 4 | 5 | 6 | 7 | ° C. | ° C. |
| 1 mm | NA | 30.8 | 33.8 | 36.1 | 37.0 | 40.3 | 40.2 | 37.0 | 36.5 | 9.5 |
| aluminum | | | | | | | | | | |
| plate | | | | | | | | | | |
| C3 | 63.1 | 28.0 | 31.7 | 35.1 | 34.0 | 38.1 | 38.5 | 37.5 | 34.7 | 10.5 |
| 2A | 51.0 | 29.9 | 32.8 | 34.1 | 33.9 | 35.3 | 35.0 | 33.1 | 33.4 | 5.4 |
| 2B | 43.1 | 29.0 | 31.7 | 33.7 | 34.7 | 36.7 | 37.0 | 35.0 | 34.0 | 8.0 |

As can be seen from the results above, the heat pipe of FIG. 2A performed the best, with an average temperature difference which was the lowest at 33.4 C, and with the lowest maximum temperature rise of only 5.4 C. This performance is unexpectedly excellent compared to the 1 mm aluminum plate and to the comparative heat pipe as shown in Figure C4 which is the subject of Comparative Example C3. Furthermore, the heat pipe of FIG. 2B also performed unexpectedly better than the heat pipe of Figure C4, with an average temperature difference which was 34 C and a maximum temperature difference that was 8 C; both of these values are unexpectedly superior to the heat pipe of Figure C4. In addition, while the performance measured by temperature difference according to embodiments of the type represented by FIG. 2B is not quite as good as FIG. 2A, the performance is nevertheless unexpectedly good, especially when considered in light of the optimum charge being substantially less for FIG. 2B embodiments compared to the all the heat pipes in the table above. This heat pipe of the present invention of the type shown in FIG. 2B have the ability to achieve excellent heat transfer performance at a relatively low cost due to the low charge required to achieve such excellent heat transfer performance.

What is claimed:

1. A heat pipe of the type which has a condenser section in which gaseous refrigerant is condensed to produce liquid refrigerant comprising:
(a) at least one closed pipe comprising:
(i) a condenser section,
(ii) a first evaporator section in fluid communication with said condenser section; and
(iii) at least a second evaporator section in fluid communication with said condenser section;
(b) refrigerant contained in said heat pipe;
(c) at least a first liquid flow path leading a first portion of liquid refrigerant condensed in said condenser section to said first evaporator section; and
(d) at least a second liquid flow path leading a second portion of liquid refrigerant condensed in said condenser section to said second evaporator section, wherein said second evaporator section comprises a reservoir holding liquid refrigerant at a location different than said first evaporator section.

2. The heat pipe of claim 1 wherein the heat pipe is configured to use gravity at least in part to return refrigerant liquid to from said condenser section to said first and said second evaporator section.

3. The heat pipe of claim 1 wherein said second liquid flow path comprises one or more obstructions in said heat pipe and being oriented at an angle with respect to the vertical direction and to divert at least a portion of said liquid refrigerant from said condenser section toward said second evaporator.

4. The heat pipe of claim 1 wherein said second evaporator section comprises a reservoir holding liquid refrigerant at a location different than said first evaporator section.

5. The heat pipe of claim 1 further comprising at least a third liquid flow path leading a third portion of liquid refrigerant condensed in said condenser section to said third evaporator section, wherein: (i) said third liquid flow path comprises one or more obstructions oriented at an angle with respect to the vertical direction and which divert at least a portion of said liquid refrigerant from said condenser section toward said third evaporator; and (ii) said third evaporator section comprises a reservoir holding liquid refrigerant at a location different than said first evaporator section and different than said second evaporator section.

6. The heat pipe of claim 5 wherein at least one of said second evaporator section and/or said third evaporator section has a total volume that is about 0.7 times (about 70%) or less than the volume of the first evaporator section.

7. The heat pipe of claim 1 wherein said second evaporator section has a total volume that is about 0.7 times (about 70%) or less than the volume of the first evaporator section.

8. The heat pipe of claim 1 wherein said liquid refrigerant comprises R-1233zd (E).

9. The heat pipe of claim 1 wherein said liquid refrigerant consists essentially of R-1233zd (E).

10. A printed circuit board (PCB) comprising:
(a) at least a first heat generating component mounted to the PCB at a first location;
(b) at least a second heat generating component mounted to the PCB at a second location different than said first location; and
(c) at least one heat pipe comprising a closed pipe comprising:
(i) a condenser section in thermal communication with cooling fluid located outside of said heat pipe,
(ii) a first evaporator section comprising a first reservoir containing liquid refrigerant in heat transfer contact with said first heat generating component;
(iii) a first liquid flow path leading a first portion of liquid refrigerant condensed in said condenser section to said reservoir in said first evaporator section;
(iii) at least a second evaporator section comprising a second reservoir at a location along said heat pipe different than said first reservoir and containing a second portion of liquid refrigerant in heat transfer contact with said at least said second heat generating component; and
(iv) at least a second liquid flow path leading said second portion of liquid refrigerant condensed in said condenser section to said reservoir in said second evaporator section.

11. A telecommunication device that includes the PCB of claim 10.

12. The PCB of claim 10 wherein at least one of aid first or second heat generating components is a 5G chip.

13. The PCB of claim 12 wherein said refrigerant comprises R-1233zd (E).

14. The PCB of claim 1 wherein said liquid refrigerant consists essentially of R-1233zd (E).

15. A method of transferring heat comprising use of a heat pipe of the type which has a condenser section in which gaseous refrigerant is condensed to produce liquid refrigerant, said method comprising:
(a) providing a closed heat pipe comprising:
(i) a condenser section in heat transfer communication with a heat sink located outside the heat pipe,
(ii) a first evaporator section in fluid communication with said condenser section and comprising a first reservoir containing liquid refrigerant; and
(iii) at least a second evaporator section in fluid communication with said condenser section and comprising a second reservoir containing liquid refrigerant;
(iv) at least a first liquid flow path leading from said condenser section to said first reservoir; and
(v) at least a second liquid flow path leading from said condenser section to said second reservoir;
(b) cooling a first component or device by thermal contact with said liquid refrigerant in said first reservoir to produce refrigerant vapor that travels to said condenser section;
(c) cooling a second component or device by thermal contact with said liquid refrigerant in said second reservoir to produce refrigerant vapor that travels to said condenser section; and
(d) condensing refrigerant vapor in the condenser section to produce condensed liquid refrigerant and returning via said first liquid flow path a first portion of said condensed liquid refrigerant to said first reservoir and returning via said second liquid flow path a second portion of said condensed liquid refrigerant to said second reservoir.

16. A method of transferring heat according to claim 15 wherein said first and second components are components located on a PCB.

17. The method of claim 15 wherein either said first and/or said second component is a 5G chip.

18. The method of claim 17 wherein said refrigerant comprises R-1233zd (E).

19. The method of claim 17 wherein said liquid refrigerant consists essentially of R-1233zd (E).

20. The method of claim 19 wherein said 5G chip is located in a telecommunications device.
